(19) United States
(12) Patent Application Publication
(10) Pub. No.: US 2026/0361104 A1
(43) Pub. Date: Nov. 12, 2026

(54) BATTERY PACK CHARGER

(71) Applicant: MILWAUKEE ELECTRIC TOOL CORPORATION, Brookfield, WI (US)

(72) Inventors: Carson G. Taylor, Madison, WI (US); Jacob D. Rosenthal, Brookfield, WI (US)

(21) Appl. No.: 19/671,934

(22) Filed: May 8, 2026

Related U.S. Application Data
(60) Provisional application No. 63/803,049, filed on May 9, 2025.

(51) Int. Cl. H02J 7/70; H05K 7/20

(52) U.S. Cl. CPC H02J 7/70; H05K 7/20172; H05K 7/20909

(57) ABSTRACT

A battery pack charger includes a housing with first and second members, a backplate, a circuit board assembly, a terminal block, and a fan assembly. The terminal block is supported by the backplate and is electrically connected to the circuit board assembly, and is configured to removably couple with a battery pack. The fan assembly is supported by the first housing member and includes a fan frame and an impeller. The first housing member includes posts that receive the circuit board, and receptacles that position the circuit board between the housing members. The charger provides a compact and efficient design for charging and discharging battery packs, with improved cooling and electrical connections.

### CROSS-REFERENCE TO RELATED APPLICATIONS

This application claims priority to U.S. Provisional Patent Application No. 63/803,049, filed on May 9, 2025, the entire contents of which are incorporated herein by reference.

### FIELD

The present disclosure relates to chargers, and more particularly to chargers that can both power and be powered by power tool battery packs.

### BACKGROUND

The development of battery pack chargers has been an ongoing process, with various approaches being taken to improve their design and functionality. One previous approach has been to use a single housing member to contain all the components of the charger, including the circuit board assembly, terminal block, and fan assembly. However, this approach has been found to be limiting in terms of the size and complexity of the charger that can be achieved. Another approach has been to use multiple housing members, but these have often been coupled together using complex and bulky fastening systems, which can add to the overall size and cost of the charger.

### SUMMARY

In some aspects, the techniques described herein relate to a battery pack charger including: a housing including a first housing member and a second housing member, the first housing member including a plurality of first apertures; a backplate supported by the first housing member and including a plurality of second apertures aligned with the plurality of first apertures; a circuit board assembly positioned within the housing; a terminal block supported by the backplate, the terminal block electrically connected to the circuit board assembly and configured to removably electrically couple with a battery pack; a fan assembly supported by the first housing member; and a plurality of fasteners, each fastener extending through one of the plurality of first apertures, one of the plurality of second apertures, and into the second housing member to couple the first housing member to the second housing member.

In some aspects, the techniques described herein relate to a battery pack charger, wherein the first housing member includes a base wall and a post extending toward the second housing member, and wherein the fan assembly is supported between the base wall and the post.

In some aspects, the techniques described herein relate to a battery pack charger, wherein: the fan assembly includes a first catch; the base wall includes a second catch; and the first catch is configured to engage the second catch to secure the fan assembly to the first housing member.

In some aspects, the techniques described herein relate to a battery pack charger, wherein: the first housing member includes a post extending toward the second housing member; the circuit board assembly includes a circuit board having a board aperture, and the post extends through the board aperture.

In some aspects, the techniques described herein relate to a battery pack charger, wherein: the post includes a first portion, a second portion, and a shelf defined at a transition between the first portion and the second portion; and the board aperture receives the second portion of the post, and the circuit board abuts the shelf.

In some aspects, the techniques described herein relate to a battery pack charger, wherein the second housing member includes an engagement portion extending toward the first housing member, and wherein the engagement portion receives the second portion of the post.

In some aspects, the techniques described herein relate to a battery pack charger, wherein the engagement portion engages the circuit board.

In some aspects, the techniques described herein relate to a battery pack charger, wherein the first housing member includes a lens integrally molded with the first housing member such that the lens is formed within the first housing member during a molding process without an air gap between the lens and the first housing member.

In some aspects, the techniques described herein relate to a battery pack charger, wherein the backplate includes at least one annular projection configured to be received within one of the plurality of first apertures of the first housing member.

In some aspects, the techniques described herein relate to a battery pack charger, wherein the backplate includes a tab engaged with a slot defined in the first housing member.

In some aspects, the techniques described herein relate to a battery pack charger, wherein the circuit board assembly includes a first circuit board and a second circuit board spaced apart from one another.

In some aspects, the techniques described herein relate to a battery pack charger, wherein the fan assembly generates an airflow between the first circuit board and the second circuit board.

In some aspects, the techniques described herein relate to a battery pack charger including: a housing including a first housing member and a second housing member coupled to the first housing member; a terminal block coupled to the housing and at least partially protruding from the first housing member, the terminal block configured to removably electrically couple with a battery pack; a circuit board assembly provided within the housing and electrically connected to the terminal block; and a fan assembly including a fan frame and a fan impeller configured to rotate relative to the fan frame, the fan frame defining a first catch; wherein the first housing member defines a second catch configured to abut the first catch to secure the fan assembly to the first housing member.

In some aspects, the techniques described herein relate to a battery pack charger, wherein the first housing member includes a base wall that defines a slot, and wherein the fan frame defines a rib that is received into the slot.

In some aspects, the techniques described herein relate to a battery pack charger, wherein: the first housing member further includes a base wall and a post extending toward the second housing member; the base wall defines the second catch; and the fan assembly is supported between the base wall and the post.

In some aspects, the techniques described herein relate to a battery pack, wherein the circuit board assembly includes a circuit board having a board aperture, and wherein the post extends through the board aperture.

In some aspects, the techniques described herein relate to a battery pack charger, including: a housing including a first housing member and a second housing member, the first housing member including a plurality of posts extending toward the second housing member, each post including a distal portion having a reduced diameter and a shoulder; a circuit board including a plurality of apertures receiving the distal portions of the posts such that the circuit board abuts the shoulders; and a terminal block coupled to the housing and at least partially protruding from the first housing member, the terminal block configured to removably electrically couple with a battery pack; wherein the first housing member includes a plurality of receptacles aligned with the posts to position the circuit board between the first housing member and the second housing member.

In some aspects, the techniques described herein relate to a battery pack charger, wherein the circuit board is captured between the first housing member and the second housing member with the receptacles contacting the circuit board.

In some aspects, the techniques described herein relate to a battery pack charger, wherein the circuit board is a first circuit board, and the battery pack charger further includes a second circuit board extending parallel to the first circuit board.

In some aspects, the techniques described herein relate to a battery pack charger, wherein the first circuit board is connected to an outlet configured to electrically connect to an accessory device, and wherein the first circuit board is operable to both charge and discharge the battery pack via the outlet.

Other aspects of the invention will become apparent by consideration of the detailed description and accompanying drawings.

### BRIEF DESCRIPTION OF THE DRAWINGS

FIG. 1 is an exploded view of a battery pack charger and a power supply.

FIG. 2 is a partial exploded view of the battery pack charger of FIG. 1.

FIG. 3 is a front view of the battery pack charger of FIG. 1.

FIG. 4 is a rear view of the battery pack charger of FIG. 1.

FIG. 5 is a perspective cross-sectional view of the battery pack charger, taken along line 5-5 of FIG. 3.

FIG. 6 is an exploded view of the battery pack charger of FIG. 1.

FIG. 7 is a perspective view of the battery pack charger of FIG. 1, with an upper housing removed.

FIG. 8 is a top view of the battery pack charger of FIG. 1, with the upper housing removed.

FIG. 9 is a side view of the battery pack charger of FIG. 1, with the upper housing removed.

FIG. 10 is a perspective view of a lower housing and a backplate of the battery pack of FIG. 1.

FIG. 11 is an enlarged view of the lower housing and the backplate of the battery pack, taken along line 11-11 in FIG. 10.

FIG. 12 is an enlarged view of the lower housing, the backplate, and the upper housing of the battery pack of FIG. 1.

FIG. 13 is an enlarged view of the lower housing, a circuit board assembly, the upper housing, and a fan assembly of the battery pack, taken along line 13-13 in FIG. 5.

FIG. 14 is an enlarged view of the lower housing and a fan assembly of the battery pack of FIG. 1.

FIG. 15 is a perspective cross-sectional view of the lower housing and the fan assembly, taken along line 15-15 in FIG. 14.

FIG. 16 is a perspective view of the fan assembly of FIG. 13.

FIG. 17 is a schematic view of an airflow path through the fan assembly and the circuit board assembly of the battery pack of FIG. 1.

FIG. 18 is a perspective view of a lens for use in the upper housing of the battery pack charger of FIG. 1.

FIG. 19 is a perspective view of a mold configured to create the upper housing of the battery pack charger of FIG. 1.

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. Also, it is to be understood that the phraseology and terminology used herein are for the purpose of description and should not be regarded as limiting.

### DETAILED DESCRIPTION

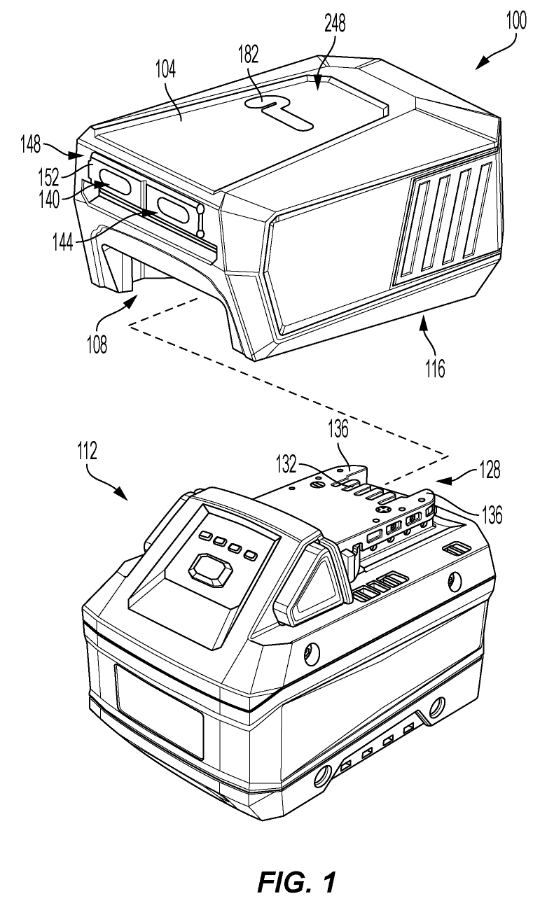

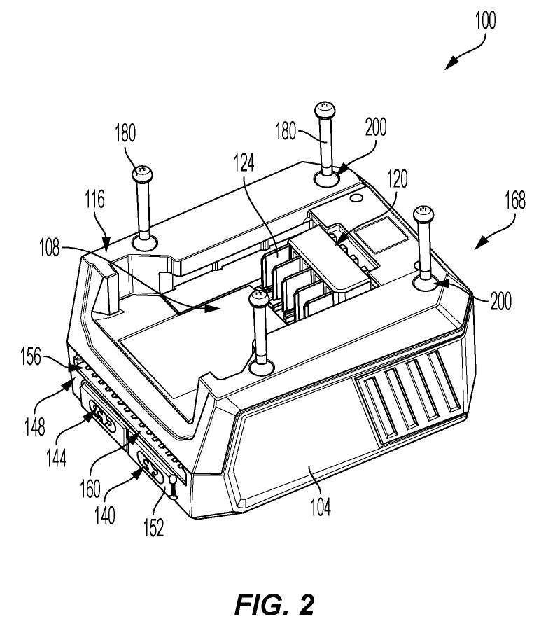

FIG. 1 illustrates an example battery pack charger and power supply 100 (also referred to as a charger 100). The charger 100 includes a charger housing 104 and a battery pack interface 108 configured to removably receive a battery pack 112. In the illustrated embodiment, the battery pack interface 108 is provided on a bottom side 116 (also referred to as a first side 116) of the charger housing 104. The battery pack interface 108 is configured to removably (e.g., slidably) receive the battery pack 112. The battery pack interface 108 includes a first terminal block 120 including a plurality of first terminals 124 (shown in FIG. 2). The first terminals 124 can include, for example, power terminals and communication terminals to connect to a corresponding second terminal block 128 of the battery pack 112.

With continued reference to FIG. 1, the battery pack 112 is, for example, a power tool battery pack 112 configured to be used to operate battery-powered power tools. In some examples, the battery pack 112 is an 18-volt (V) nominal voltage lithium-ion-chemistry-based power tool battery pack. In other examples, the battery pack 112 may have a different nominal voltage (e.g., 12 V, 36 V, 72 V, etc.) and/or different chemistry (e.g., nickel-based). The second terminal block 128 can include a plurality of second terminals 132. The second terminals 132 are configured to couple to the first terminals 124 of the charger 100 to connect the charger 100 to the battery pack 112. The battery pack 112 can include two parallel rails 136 spaced apart from each other and positioned on each side of the second terminal block 128. The rails 136 can facilitate the sliding connection of the charger 100 and the battery pack 112.

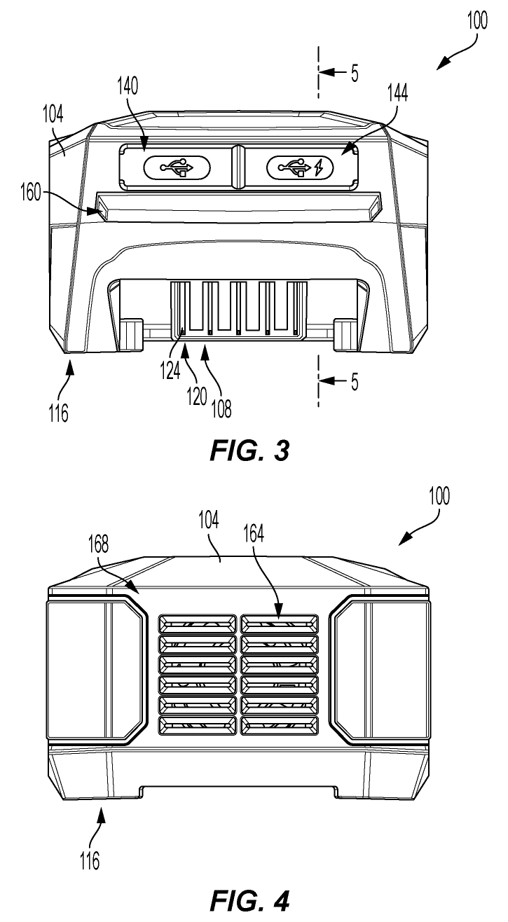

With reference to FIGS. 1-3, the charger 100 includes a first outlet 140 and a second outlet 144 provided on a front side 148 (also referred to as a second side 148) of the charger housing 104. Although not shown, the charger 100 can include a user interface (e.g., provided on a side surface of the charger housing 104). The user interface can include a display (e.g., an LCD display, an LED display, an e-ink display, etc.), an enable button for the first outlet 140, and an enable button for the second outlet 144. The user interface can provide indications (e.g., via the display) regarding the status of the charger 100. For example, the user interface may show a fuel gauge relating to the battery pack 112, a status of the first outlet 140, a status of the second outlet 144, or any other status of the charger 100. The illustrated first and second outlets 140, 144 are each positioned behind covers 152. The covers 152 can, for example, inhibit debris (e.g., dust) from entering the first and second outlets 140, 144. While the first and second outlets 140, 144 are illustrated in FIGS. 1-3, other examples of the charger 100 can include any number of outlets.

The first and second outlets 140, 144 can be DC outlets. The first and second outlets 140, 144 can each output a different amount of power. For example, the first outlet 140 can output a lower power than the second outlet 144. The first outlet 140 and/or the second outlet 144 can be used for charging and discharging the battery pack 112. In the illustrated embodiment, the first outlet 140 can be used for charging and discharging the battery pack 112. The first and second outlets 140, 144 can be Universal Serial Bus-C (USB-C) Power Delivery (PD) outlets configured to provide a power output at a predetermined maximum (e.g., 100 watts). In other examples, additional outlets can be another type of outlet (e.g., USB-A, USB-B, etc.) configured to provide a power output at a higher or lower predetermined maximum (e.g., 15 watts, 120 watts).

With reference to FIG. 2, the charger 100 includes a plurality of first vents 156. The first vents 156 are apertures in the front side 148 of the charger housing 104. The first vents 156 allow air to flow into the charger housing 104 and out of the charger housing 104 to, for example, cool components of the charger 100. The first vents 156 are positioned inside a groove 160 in the front side of the charger housing 104. The illustrated first vents 156 are positioned below the first and second outlets 140, 144. Stated another way, the first vents 156 are positioned closer to the bottom side 116 of the charger housing 104 than the first and second outlets 140, 144.

With reference now to FIG. 4, the charger 100 includes a plurality of second vents 164. The second vents 164 are apertures in a rear side 168 of the charger housing 104. The second vents 164 allow air to flow into the charger housing 104 and out of the charger housing 104 to, for example, cool components of the charger 100.

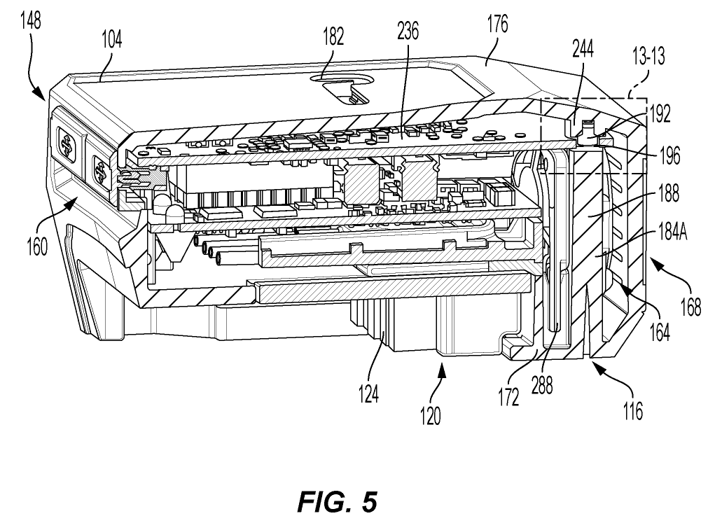

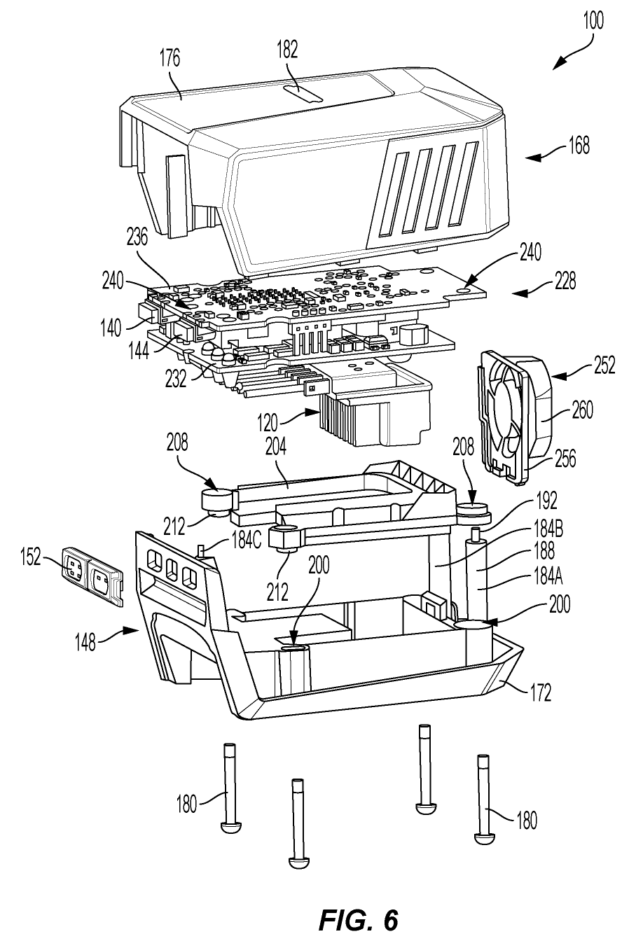

With reference to FIGS. 5 and 6, the charger housing 104 includes a lower housing 172 (also referred to as a first housing member 172) and an upper housing 176 (also referred to as a second housing member 176). The lower housing 172 is coupled to the upper housing 176 by a plurality of fasteners 180 (shown in FIG. 6). The fasteners 180 can be, for example, screws, bolts, etc. The upper housing 176 includes a lens 182 (also referred to as an optic 182). Light from, for example, an LED can be selectively emitted through the lens 182. The lower housing 172 includes a plurality of posts extending away from the bottom side 116 of the charger housing 104. The illustrated plurality of posts includes a first post 184A, a second post 184B, and a third post 184C. Each of the first, second, and third posts 184A-184C includes a first section 188 (also referred to as a lower section 188) and a second section 192 (also referred to as an upper section 192). The first sections 188 are positioned between the bottom side 116 of the charger housing 104 and the second sections 192. Each first section 188 includes a diameter greater than a diameter of the second sections 192. Stated another way, each first section 188 is larger than the associated second section 192. As such, each of the first, second, and third posts 184A-184C defines a shelf 196 (also referred to as a shoulder 196) at the transition between the first section 188 and the second section 192. The first and second posts 184A, 184B are positioned adjacent the rear side 168 of the charger housing 104. The third post 184C is positioned adjacent the front side 148 of the charger housing 104. The illustrated first, second, and third posts 184A-184C are arranged in a triangular shape. In other embodiments, the lower housing 172 can include a different number of posts arranged in any suitable arrangement.

With reference to FIG. 6, the lower housing 172 includes a plurality of fastener apertures 200. Each fastener 180 is configured to extend through an associated fastener aperture 200 and be received in a recess (not shown) in the upper housing 176. Each fastener 180 can be threadably coupled to the associated recess in the upper housing 176 to couple the lower housing 172 to the upper housing 176.

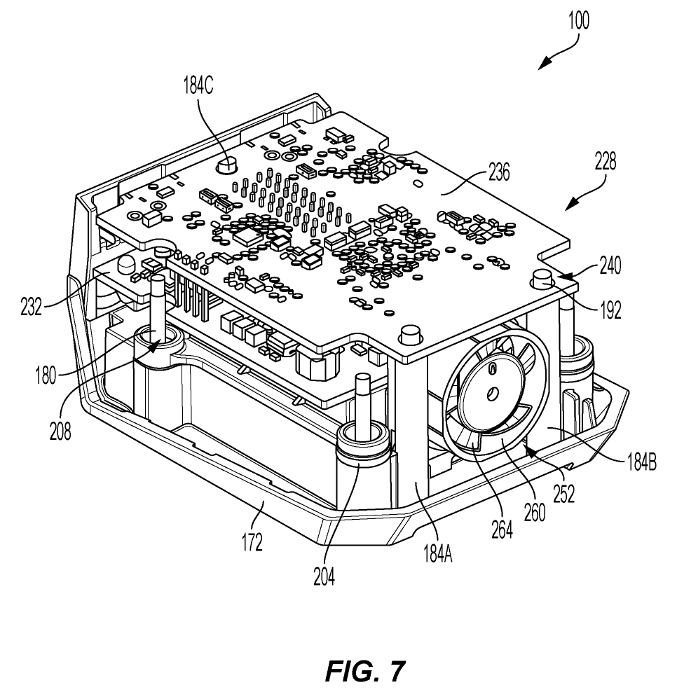

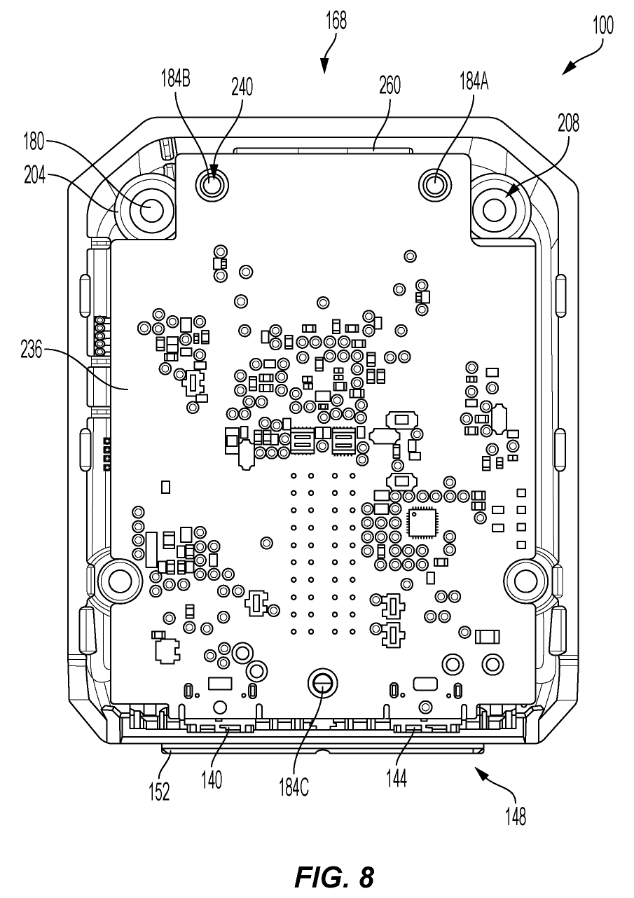

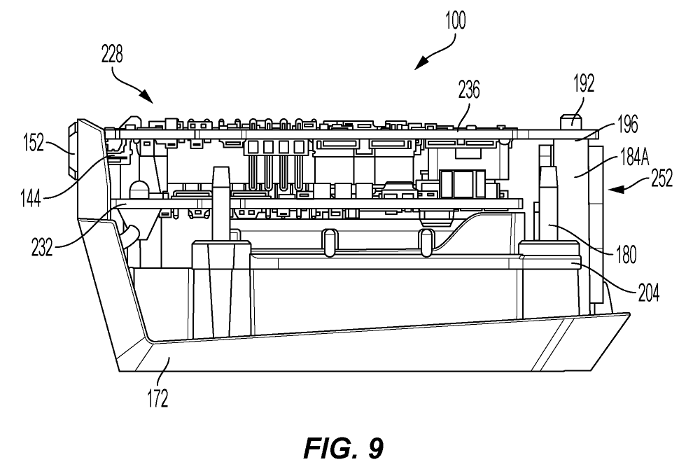

With reference to FIGS. 6-10, the charger 100 includes a backplate 204 (also referred to as a terminal block holder 204) engaged with the lower housing 172. The backplate 204 supports the first terminal block 120. The backplate 204 includes a plurality of terminal apertures 208. Each terminal aperture 208 is aligned with an associated fastener aperture 200 in the lower housing 172. The backplate 204 can include an annular projection 212 adjacent one or more of the terminal apertures 208. Each annular projection 212 can be, for example, received in an associated fastener aperture 200 to improve the connection between the backplate 204 and the lower housing 172. The improved connection can assist in assembly of the charger 100. In the illustrated embodiment, the backplate 204 includes an annular projection 212 surrounding each of the terminal apertures 208 adjacent the front side 148 of the charger housing 104. Each fastener 180 is configured to extend through an associated terminal aperture 208 to couple the backplate 204 to the lower and upper housings 172, 176.

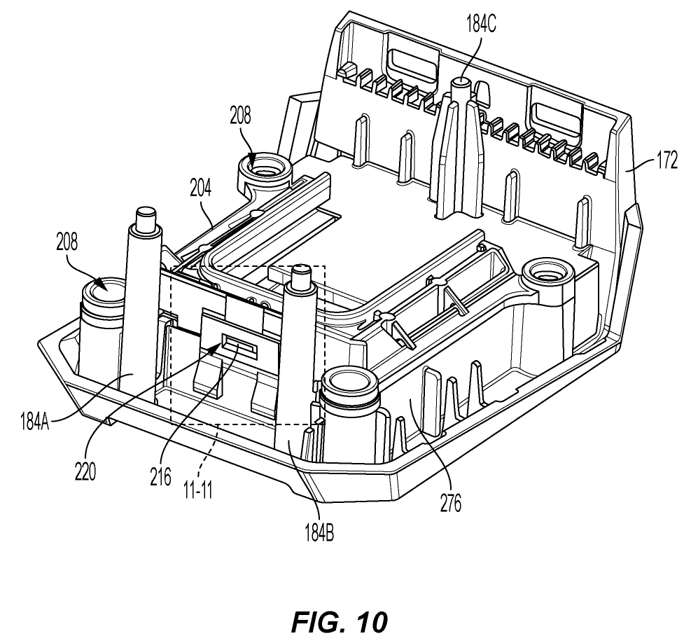

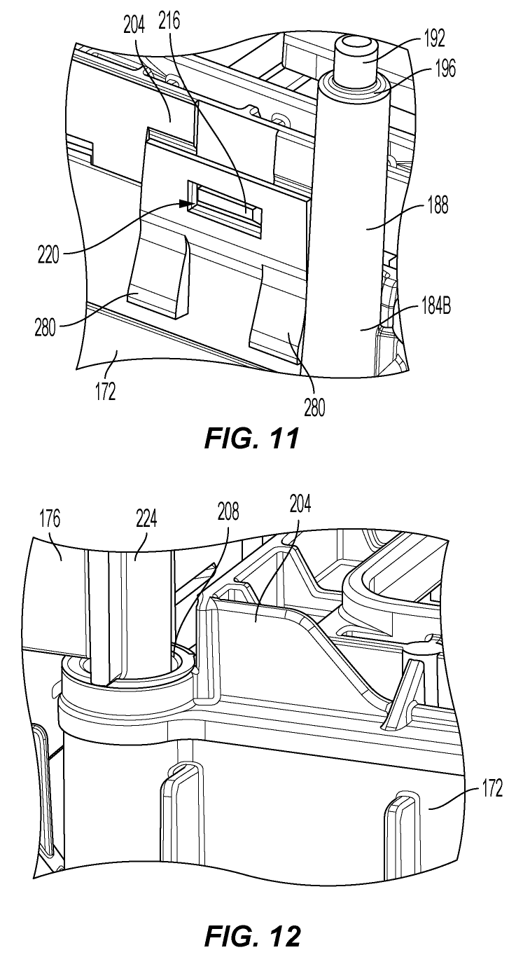

With reference now to FIGS. 10 and 11, the backplate 204 includes a tab 216 extending toward the rear side 168 of the charger housing 104. The tab 216 is received in a slot 220 in the lower housing 172. The engagement between the tab 216 and the slot 220 can improve or facilitate the connection between the backplate 204 and the lower housing 172 during assembly. In some embodiments, the backplate 204 and the lower housing 172 can include different or additional mating components to improve or facilitate the assembly of the charger 100.

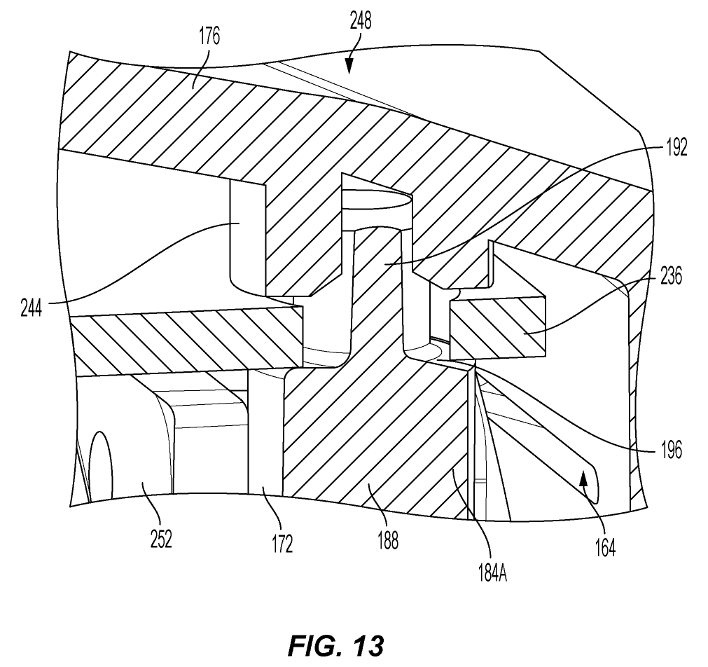

With reference now to FIG. 12, the upper housing 176 includes a plurality of arms 224 (only one shown in FIG. 12). Each arm 224 is received in an associated terminal aperture 208. In some embodiments, each arm 224 can also extend into an associated fastener aperture 200 in the lower housing 172. Each arm 224 can be hollow to receive an associated fastener 180.

With reference to FIGS. 6-9, the charger 100 includes a circuit board assembly 228. The circuit board assembly 228 is configured to control operation of the charger 100. The circuit board assembly 228 can be connected to the user interface of the charger 100. The circuit board assembly 228 can be connected to the first terminal block 120. The circuit board assembly 228 can be connected to the first and second outlets 140, 144. The illustrated circuit board assembly 228 includes a lower circuit board 232 (also referred to as a first circuit board 232) and an upper circuit board 236 (also referred to as a second circuit board 236). The illustrated lower and upper circuit boards 232, 236 extend parallel with each other and are spaced apart from one another. The illustrated lower and upper circuit boards 232, 236 extend horizontally. Stated another way, the lower and upper circuit boards 232, 236 extend between the front side 148 and the rear side 168 of the charger housing 104.

With continued reference to FIGS. 6-9, the upper circuit board 236 includes a plurality of board apertures 240. Each board aperture 240 receives an associated post of the lower housing 172. More specifically, each second section 192 of the first, second, and third posts 184A-184C extends through an associated board aperture 240. The upper circuit board 236 rests on the shelves 196 of the first, second, and third posts 184A-184C to support the circuit board assembly 228 within the charger housing 104. The illustrated upper circuit board 236 includes three board apertures 240 to match the number of posts of the lower housing 172. In other embodiments, the upper circuit board 236 can include a different number of board apertures 240 to match an associated number of posts of the lower housing 172 (e.g., two, four, five, etc.).

With reference now to FIG. 13, the upper circuit board 236 is positioned between the lower housing 172 and the upper housing 176. The upper housing 176 includes a plurality of receptacles 244 (only one shown in FIG. 13; also referred to as receiving portions 244). Each receptacle 244 receives an associated second section 192 of a post of the lower housing 172. The illustrated receptacles 244 are hollow posts extending away from a top side 248 of the charger housing 104. Each receptacle 244 extends toward the upper circuit board 236. In some embodiments, the receptacle 244 engages the upper circuit board 236. In other embodiments, the receptacle 244 may be spaced apart from the upper circuit board 236. The upper circuit board 236 can be referred to as being sandwiched between the lower housing 172 and the upper housing 176. More specifically, the upper circuit board 236 can be referred to as being sandwiched between the shelves 196 of the first, second, and third posts 184A-184C of the lower housing 172 and the receptacles 244 of the upper housing 176.

With reference now to FIGS. 5-9, 14, and 15, the charger 100 includes a fan assembly 252. The fan assembly 252 is configured to blow air through the charger housing 104 to cool components of the charger 100 (e.g., the circuit board assembly 228). The fan assembly 252 includes a fan frame 256 and a fan impeller 264 rotatably supported relative to the fan frame 256. The fan frame 256 includes a fan shroud 260 that closely surrounds the fan impeller 264. The fan assembly 252 is positioned near the rear side 168 of the charger housing 104.

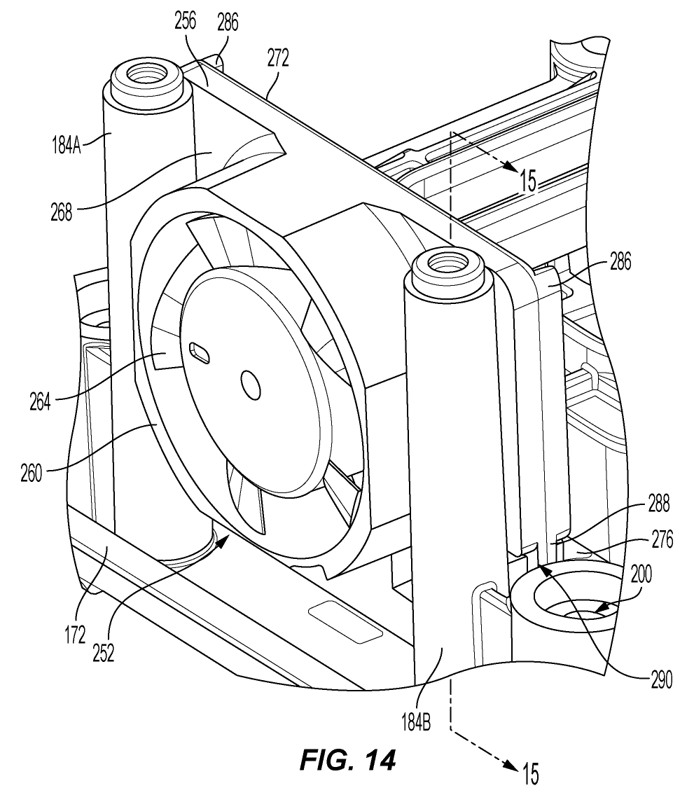

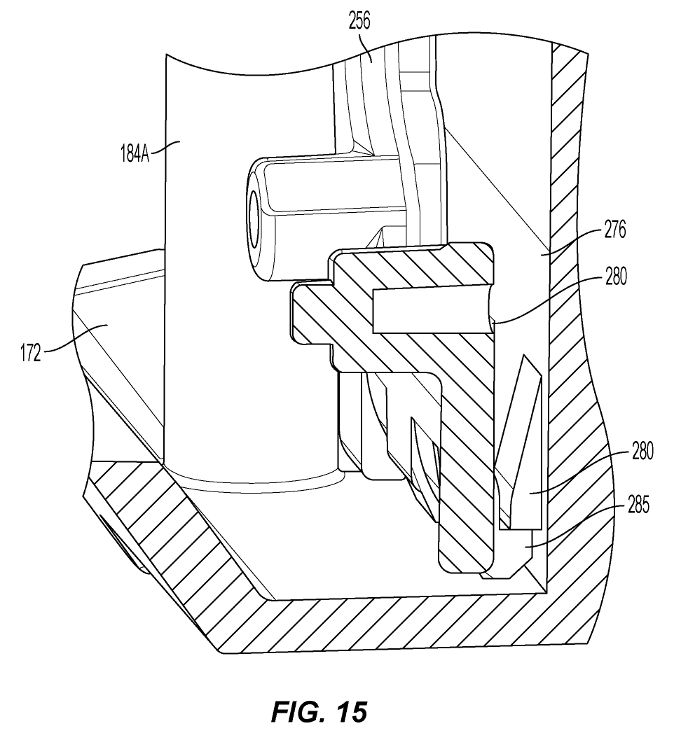

With reference now to FIGS. 14 and 15, the fan assembly 252 is coupled to the lower housing 172. The fan frame 256 defines a first side 268 and a second side 272 opposite the first side 268. The fan shroud 260 extends from the first side 268 of the fan frame 256. The first and second posts 184A, 184B of the lower housing 172 engage the first side 268 of the fan frame 256. The lower housing 172 includes a base wall 276 facing toward the first and second posts 184A, 184B and including a plurality of second catches 280. The second catches 280 protrude from the base wall 276 in a direction toward the first and second posts 184A, 184B. The fan assembly 252 includes a plurality of snap arms 284. Each snap arm 284 defines a first catch 285 configured to engage a corresponding one of the second catches 280 to thereby couple the fan assembly 252 to the lower housing 172. The fan assembly 252 can include a plurality of ribs 286 to further secure the fan assembly 252 to the lower housing 172. The illustrated fan assembly 252 includes two ribs 286 extending from the second side 272 of the fan frame 256. The ribs 286 are provided on opposite ends of the fan frame 256.

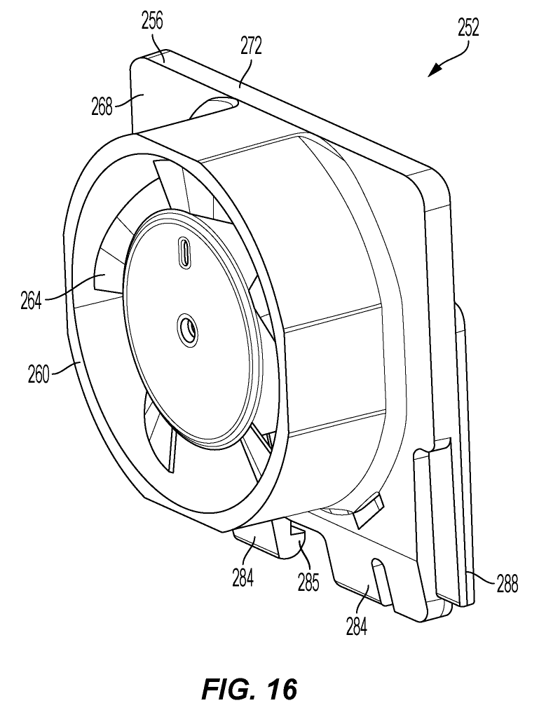

With reference now to FIG. 16, the fan assembly 252 includes a rib 288 on each side of the fan frame 256. Each rib 288 is received within a slot 290 defined by the base wall 276 adjacent the first and second posts 184A, 184B of the lower housing 172 to couple the fan assembly 252 to the lower housing 172. Each illustrated rib 288 is thinner than the surrounding portions of the fan frame 256. The first and second catches 285, 280 abut one another to secure the fan frame 256 to the lower housing 172 with the ribs 288 residing within the slots 290.

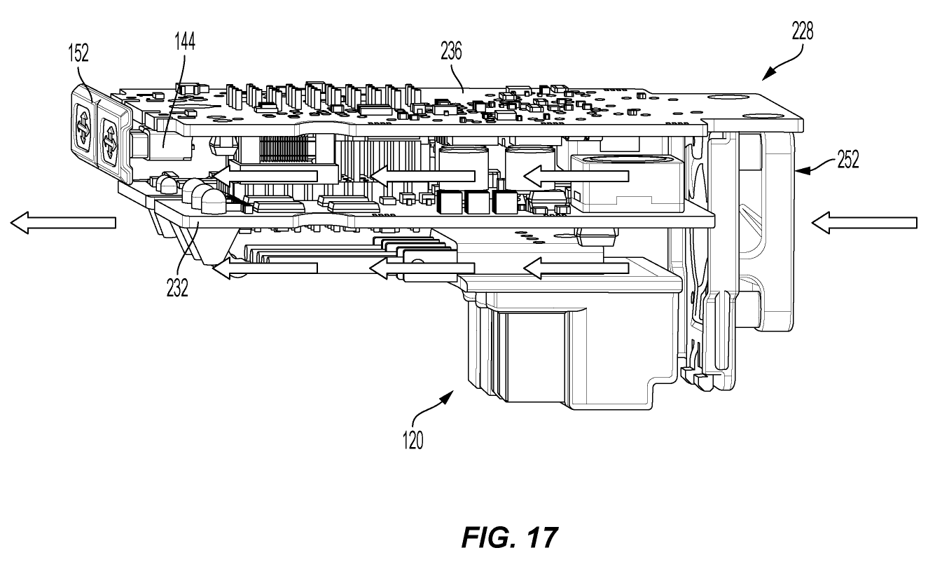

With reference now to FIG. 17, the fan assembly 252 is configured to direct a flow of air through the charger housing 104. More specifically, the fan assembly 252 is configured to direct air into the charger housing 104 through the second vents 164 (shown in FIG. 4). As such, the second vents 164 can be referred to as inlet vents 164. Once inside the charger housing 104, the fan assembly 252 directs the air to flow toward the front side 148 of the charger housing 104. The air can flow past the first terminal block 120 to cool the first terminal block 120. The air flows past the circuit board assembly 228 to cool the circuit board assembly 228. The air can flow between the lower circuit board 232 and the upper circuit board 236. Additionally or alternatively, the air can flow between the lower circuit board 232 and the first terminal block 120. The air can exit the charger housing 104 through the first vents 156 (shown in FIG. 2). As such, the first vents 156 can be referred to as outlet vents 156. In some embodiments, the airflow path can be reversed. As such, the air can flow into the charger housing 104 through the first vents 156, and air can flow out of the charger housing 104 through the second vents 164.

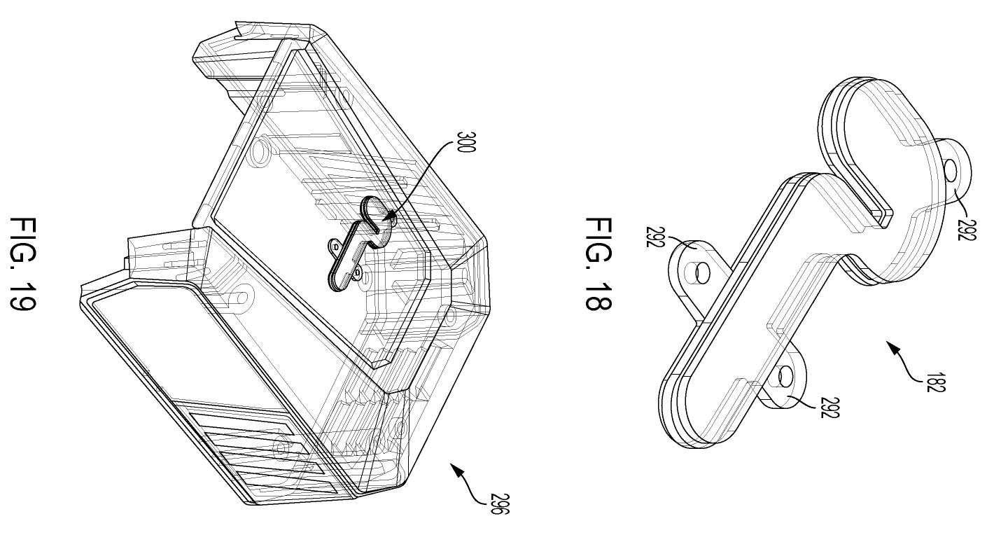

With reference now to FIG. 18, the lens 182 includes a plurality of mold mounts 292. The mold mounts 292 are configured to assist in the manufacturing of the upper housing 176. The lens 182 includes a complicated lens shape. The illustrated lens 182 has a shape resembling a question mark. In other embodiments, the lens 182 can have a different shape.

FIG. 19 illustrates a mold 296 for the upper housing 176. The mold 296 can be a mold used in, for example, an injection molding process to create the upper housing 176. The mold 296 includes a mold aperture 300. The mold aperture 300 is configured to receive the lens 182 (shown in FIG. 18) prior to receiving, for example, an injection molding thermoplastic (e.g., polycarbonate, acrylonitrile butadiene styrene (ABS), nylon, etc.). Once the upper housing 176 has been molded, the lens 182 is integrally formed with the rest of the upper housing 176. Molding the lens 182 into the upper housing 176 inhibits air gaps from being formed between the lens 182 and the rest of the upper housing 176. The lack of air gaps can increase the resistance to electrostatic discharge of the upper housing 176 when, for example, an LED beneath the lens 182 emits light.

To assemble the charger 100, the backplate 204 is engaged with the lower housing 172. Each terminal aperture 208 of the backplate 204 is aligned with an associated fastener aperture 200 of the lower housing 172. In embodiments with annular projections 212 on the backplate 204, each annular projection 212 can be received in an associated terminal aperture 208. The tab 216 of the backplate 204 is received in the slot 220. The fan assembly 252 is engaged with the lower housing 172. The ribs 288 of the fan assembly 252 are received between the base wall 276 and the first and second posts 184A, 184B of the lower housing 172. Each snap arm 284 of the fan assembly 252 engages an associated second catch 280 of the lower housing 172 to couple the fan assembly 252 to the lower housing 172. The ribs 286 of the fan assembly 252 can further engage the lower housing 172 to improve the connection between the fan assembly 252 and the lower housing 172. The first terminal block 120 is engaged with the backplate 204. The circuit board assembly 228 is engaged with the lower housing 172. More specifically, each board aperture 240 of the upper circuit board 236 receives a second section 192 of an associated post 184A-184C, such that the upper circuit board 236 is supported on the shelves 196 of the posts 184A-184C. The upper housing 176 is engaged with the backplate 204 and the lower housing 172. More specifically, each arm 224 of the upper housing 176 is received in an associated terminal aperture 208 of the backplate 204. Each receptacle 244 of the upper housing 176 receives a second section 192 of an associated post 184A-184C. Each receptacle 244 can engage the upper circuit board 236 to sandwich the upper circuit board 236 between the upper housing 176 and the lower housing 172. Each fastener 180 extends through an associated fastener aperture 200 of the lower housing 172, through an associated terminal aperture 208 of the backplate 204, and into an associated arm 224 of the upper housing 176. Each fastener 180 can be coupled to the associated arm 224 to couple the components of the charger 100 together. In the illustrated embodiment, the charger 100 includes four fasteners 180 to couple the components of the charger 100 together. In other examples, the charger 100 can include a different number of fasteners 180 (e.g., two, three, five, etc.).

During operation, the charger 100 can be coupled to a battery pack 112. The charger 100 can be used to draw power from the battery pack 112 and to provide power to the battery pack 112 to charge the battery pack 112. To draw power from the battery pack 112, a cord can connect a device (e.g., a phone, a different battery, etc.) to the charger 100 via the first outlet 140 or the second outlet 144. The charger 100 can transfer power from the battery pack 112, through the charger 100, and into the device to power the device. To provide power to the battery pack 112 to charge the battery pack 112, a power cord can connect a power source (e.g., a generator, a wall outlet power source, etc.) via the first outlet 140 or the second outlet 144. The charger 100 can transfer power from the power source, through the charger 100, and into the battery pack 112 to charge the battery pack 112.

Although the disclosure has been described in detail with reference to certain preferred embodiments, variations and modifications exist within the scope and spirit of one or more independent aspects of the disclosure as described.

What is claimed is:

1. A battery pack charger comprising:
a housing including a first housing member and a second housing member, the first housing member including a plurality of first apertures;
a backplate supported by the first housing member and including a plurality of second apertures aligned with the plurality of first apertures;
a circuit board assembly positioned within the housing;
a terminal block supported by the backplate, the terminal block electrically connected to the circuit board assembly and configured to removably electrically couple with a battery pack;
a fan assembly supported by the first housing member; and
a plurality of fasteners, each fastener extending through one of the plurality of first apertures, one of the plurality of second apertures, and into the second housing member to couple the first housing member to the second housing member.

2. The battery pack charger of claim 1, wherein the first housing member includes a base wall and a post extending toward the second housing member, and wherein the fan assembly is supported between the base wall and the post.

3. The battery pack charger of claim 2, wherein:
the fan assembly includes a first catch;
the base wall includes a second catch; and
the first catch is configured to engage the second catch to secure the fan assembly to the first housing member.

4. The battery pack charger of claim 1, wherein:
the first housing member includes a post extending toward the second housing member;
the circuit board assembly includes a circuit board having a board aperture, and
the post extends through the board aperture.

5. The battery pack charger of claim 4, wherein:
the post includes a first portion, a second portion, and a shelf defined at a transition between the first portion and the second portion; and
the board aperture receives the second portion of the post, and
the circuit board abuts the shelf.

6. The battery pack charger of claim 5, wherein the second housing member includes an engagement portion extending toward the first housing member, and wherein the engagement portion receives the second portion of the post.

7. The battery pack charger of claim 6, wherein the engagement portion engages the circuit board.

8. The battery pack charger of claim 1, wherein the first housing member includes a lens integrally molded with the first housing member such that the lens is formed within the first housing member during a molding process without an air gap between the lens and the first housing member.

9. The battery pack charger of claim 1, wherein the backplate includes at least one annular projection configured to be received within one of the plurality of first apertures of the first housing member.

10. The battery pack charger of claim 1, wherein the backplate includes a tab engaged with a slot defined in the first housing member.

11. The battery pack charger of claim 1, wherein the circuit board assembly includes a first circuit board and a second circuit board spaced apart from one another.

12. The battery pack charger of claim 11, wherein the fan assembly generates an airflow between the first circuit board and the second circuit board.

13. A battery pack charger comprising:
a housing including a first housing member and a second housing member coupled to the first housing member;
a terminal block coupled to the housing and at least partially protruding from the first housing member, the terminal block configured to removably electrically couple with a battery pack;
a circuit board assembly provided within the housing and electrically connected to the terminal block; and
a fan assembly including a fan frame and a fan impeller configured to rotate relative to the fan frame, the fan frame defining a first catch;
wherein the first housing member defines a second catch configured to abut the first catch to secure the fan assembly to the first housing member.

14. The battery pack charger of claim 13, wherein the first housing member includes a base wall that defines a slot, and wherein the fan frame defines a rib that is received into the slot.

15. The battery pack charger of claim 14, wherein:
the first housing member further includes a base wall and a post extending toward the second housing member;
the base wall defines the second catch; and
the fan assembly is supported between the base wall and the post.

16. The battery pack charger of claim 15, wherein the circuit board assembly includes a circuit board having a board aperture, and wherein the post extends through the board aperture.

17. A battery pack charger, comprising:
a housing including a first housing member and a second housing member, the first housing member including a plurality of posts extending toward the second housing member, each post including a distal portion having a reduced diameter and a shoulder;
a circuit board including a plurality of apertures receiving the distal portions of the posts such that the circuit board abuts the shoulders; and
a terminal block coupled to the housing and at least partially protruding from the first housing member, the terminal block configured to removably electrically couple with a battery pack;
wherein the first housing member includes a plurality of receptacles aligned with the posts to position the circuit board between the first housing member and the second housing member.

18. The battery pack charger of claim 17, wherein the circuit board is captured between the first housing member and the second housing member with the receptacles contacting the circuit board.

19. The battery pack charger of claim 17, wherein the circuit board is a first circuit board, and the battery pack charger further includes a second circuit board extending parallel to the first circuit board.

20. The battery pack charger of claim 19, wherein the first circuit board is connected to an outlet configured to electrically connect to an accessory device, and wherein the first circuit board is operable to both charge and discharge the battery pack via the outlet.
